(19) United States
(12) Patent Application Publication
(10) Pub. No.: US 2026/0123008 A1
(43) Pub. Date: Apr. 30, 2026

(54) INTEGRATED CIRCUIT AND METHOD FOR FORMING INTEGRATED CIRCUIT WITH ADVANCED ETCHING PROCESS

(71) Applicant: Taiwan Semiconductor Manufacturing Co., Ltd., Hsinchu (TW)

(72) Inventors: Kuei-Yu KAO, Hsinchu (TW); Chiung-Yu CHO, Hsinchu (TW)

(21) Appl. No.: 18/932,243

(22) Filed: Oct. 30, 2024

(51) Int. Cl. H01L 29/417; H01L 29/06; H01L 29/423; H01L 29/66; H01L 29/775; H01L 29/786

(52) U.S. Cl. CPC H10D 64/258; H10D 30/014; H10D 62/116; H10D 64/017; H10D 64/018; H10D 64/514; H10D 30/43; H10D 30/6735; H10D 30/6757; H10D 62/121

(57) ABSTRACT

A process for forming an integrated circuit includes forming a semiconductor fin above a substrate of a wafer and forming a sacrificial gate structure overlying the semiconductor fin. The process includes removing a byproduct layer from the sacrificial gate structure by performing a multi-step etching process including a dry etching process followed by a wet etching process.

### BACKGROUND

The semiconductor integrated circuit industry has experienced exponential growth. Technological advances in integrated circuit materials and design have produced generations of integrated circuits where each generation has smaller and more complex circuits than the previous generation. In the course of integrated circuit evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing integrated circuits.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1-24 are perspective and cross-sectional views of an integrated circuit at various stages of processing, in accordance with some embodiments.

FIG. 25A is an illustration of a dry etching tool, in accordance with some embodiments.

FIG. 25B is an illustration of a wet etching tool in accordance with some embodiments.

FIGS. 26A and 26B are graphs associated with transistor characteristics, in accordance with some embodiments.

FIG. 27 is a flow diagram of a method for forming an integrated circuit, in accordance with some embodiments.

FIG. 28 is a flow diagram of a method for forming an integrated circuit, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Terms indicative of relative degree, such as “about,” “substantially,” and the like, should be interpreted as one having ordinary skill in the art would in view of current technological norms.

The present disclosure is generally related to semiconductor devices, and more particularly to field-effect transistors (FETs), such as planar FETs, three-dimensional fin FETs (FinFETs), or nanostructure devices. Examples of nanostructure devices include gate-all-around (GAA) devices, nanosheet FETs (NSFETs), nanowire FETs (NWFETs), and the like. In advanced technology nodes, active area spacing between nanostructure devices is generally uniform, source/drain epitaxy structures are symmetrical, and a metal gate surrounds four sides of the nanostructures (e.g., nanosheets). Gate-drain capacitance (“Cgd”) is increased due to larger metal gate endcap and increased source/drain epitaxy size.

Embodiments of the disclosure provide a method of forming transistors that results in improved transistor characteristics. A plurality of semiconductor fins are formed above a substrate extending in a first direction. A plurality of sacrificial gate structures are formed extending in a second direction and overlying the semiconductor fins. Patterning of the sacrificial gate structures results in a byproduct layer covering the sacrificial gate structures in the semiconductor fins. More particularly, a thick accumulation of the byproducts may collect at bottom junctions between semiconductor fins and sacrificial gate structures. Embodiments of the present disclosure advantageously utilize a multistep etching process including a combination of a dry etch and a wet etch to effectively remove the byproduct layer and the thick accumulation. Additionally, sacrificial dielectric nanostructures are utilized to release the channels of gate all around transistors formed in conjunction with the fins. The result of these processes is that uniform channel thickness is maintained and gate metals do not include protrusions that risk leakage or shorting with source/drain regions. Transistor performance is greatly improved, as are wafer yields. More particularly, channel resistance is reduced and AC/DC performance of transistors is improved.

The transistors may be termed “nanostructure transistors” and the channels may be termed “semiconductor nanostructures”. The nanostructure transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the nanostructure transistor structure.

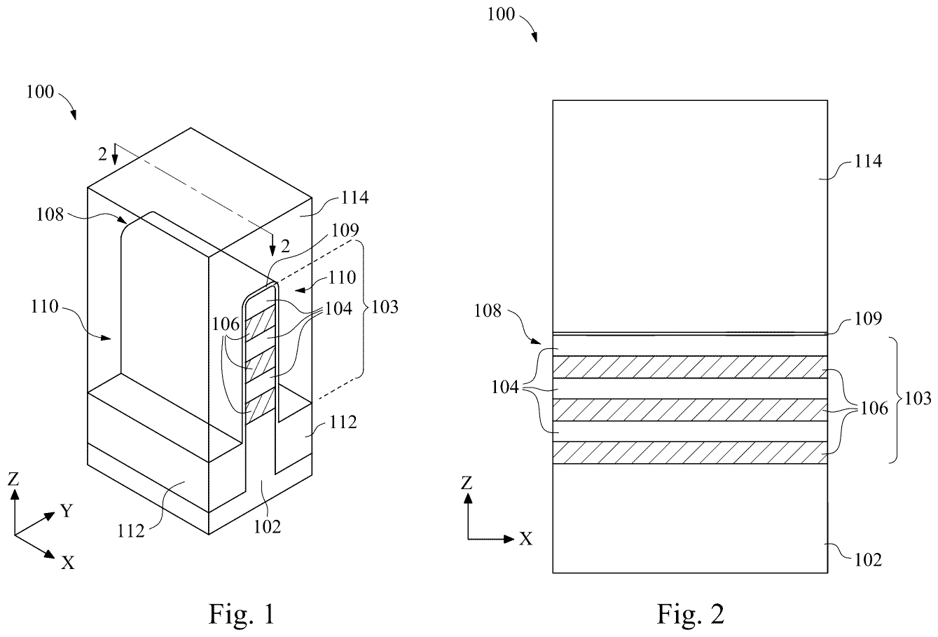

FIGS. 1-24 are perspective and side-sectional views of a portion of an integrated circuit 100 at various stages of processing, in accordance with some embodiments. The fabrication process results in a plurality of transistors 154, as will be described in further detail below. While the description herein focuses primarily on formation of transistors including stacked channels, in practice, principles of the present disclosure extend to FinFET transistors, fork sheet transistors, CFET transistors, VFET transistors, and CMOS transistors.

FIG. 1 is a perspective view of the integrated circuit 100 at an intermediate state of processing, in accordance with some embodiments. The integrated circuit 100 includes a substrate 102. The substrate 102 may be a semiconductor substrate, such as a bulk semiconductor, or the like, which may be doped (e.g., with a p-type or an n-type dopant) or undoped. In an exemplary embodiment, the substrate includes silicon. Alternatively, the substrate 102 can include other semiconductor materials such as germanium; a compound semiconductor including silicon carbide, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof. Other substrates, such as single-layer, multi-layered, or gradient substrates may be used.

The integrated circuit 100 includes a semiconductor stack 103 including a plurality of semiconductor layers 104 and sacrificial semiconductor layers 106 alternating with each other. As will be set forth in further detail below, the semiconductor layers 104 will be patterned to form stacked channels of a plurality of transistors. As set forth in more detail below, the sacrificial semiconductor layers 106 will eventually be entirely removed and are utilized to enable forming gate metals and other structures around the channels. In FIG. 1, three semiconductor layers 104 and three sacrificial semiconductor layers 106 are illustrated. In some embodiments, the multi-layer stack 103 may include fewer or more layers than are shown in FIG. 1.

In some embodiments, the semiconductor layers 104 may be formed of a first semiconductor material suitable, such as silicon, silicon carbide, or the like, and the sacrificial semiconductor layers 106 may be formed of a second semiconductor material, such as silicon germanium or the like. In an exemplary embodiment, the semiconductor layers 104 are silicon and the semiconductor layers 106 are silicon germanium. Each of the layers of the multi-layer stack 103 may be epitaxially grown using a process such as chemical vapor deposition (CVD), atomic layer deposition (ALD), vapor phase epitaxy (VPE), molecular beam epitaxy (MBE), or the like.

Due to high etch selectivity between the materials of the semiconductor layers 104 and the sacrificial semiconductor layers 106, the sacrificial semiconductor layers 106 of the second semiconductor material may be removed without significantly etching the semiconductor layers 104 of the first semiconductor material, thereby allowing the semiconductor layers 104 to be released to form stacked channel regions of transistors, as will be set forth in more detail below.

In FIG. 1, the stack 103 has been patterned to form a plurality of semiconductor fins 108. Only single semiconductor fin 108 as shown in FIG. 1. However, in practice, a plurality of semiconductor fins 108 are formed extending parallel to each other in the X direction and spaced apart from each other in the Y direction.

The semiconductor fins 108 can be formed by depositing a hard mask layer on the stack 103. The hard mask layer can include a dielectric material. The dielectric material can include SiN, SiCN, SiOCN, SiOC, or other suitable dielectric materials. The hard mask layer can have a thickness between 3 nm and 20 nm. The hard mask layer is then patterned in accordance with a photolithography process to form strips extending in the Y direction in the pattern of the semiconductor fins 108 that will be formed. After patterning of the hard mask layer, trenches 110 are formed in the stack 103 and in the substrate 102. The trenches 110 can be formed with an anisotropic etching process that etches in the downward direction. The etching process defines the semiconductor fins 108 by forming trenches 110 in the presence of the hard mask layer. The result of the etching process is that a plurality of semiconductor fins 108 are formed from the stack 103. The semiconductor fins 108 extend in the X direction.

In FIG. 1, shallow trench isolation regions 112 have been formed by depositing a dielectric material in the trenches 110 between fins 108. The shell dielectric layer may be deposited by chemical vapor deposition (CVD), atomic layer deposition (ALD), physical vapor deposition (PVD), or other suitable deposition processes. In an exemplary embodiment, the dielectric material includes silicon oxide. However, the dielectric material can include SiN, SiCN, SiOC, SiOCN, or other dielectric materials without departing from the scope of the present disclosure. A chemical mechanical planarization (CMP) process has been performed to remove excess material of the shallow trench isolation region 112 from the top surface of the hard mask layer.

After deposition of the material of the trench isolation regions 112, the hard mask layer is removed. The hard mask layer can be removed with one or more etching processes. The etching processes can include a wet etch, a dry etch, or other suitable etching processes.

After remove of the hard mask layer, an etch-back process is performed to recess the top of the shallow trench isolation regions 112, in accordance with some embodiments. The etchback process results in the completion of the shallow trench isolation regions 112. The top surface of the shallow trench isolation region 112 is lower than the lowest semiconductor layer 104 of the fin 108.

As shown in FIG. 1, the integrated circuit 100 includes a dielectric layer 109 formed on the fin 108. The dielectric layer 109 is a contact etch stop layer (CESL). The dielectric layer 109 covers the top fin 108. The dielectric layer 11 and may also cover a top surface of the trench isolation region 112. In some embodiments, the dielectric layer 109 includes SiCN, SiOCN, SiOC SiO, SiN, or other suitable dielectric materials. The dielectric layer 109 can have a thickness between 1 nm and 10 nm. Other materials and thicknesses may be utilized for the dielectric layer 109 without departing from the scope of the present disclosure.

In FIG. 1, a sacrificial gate layer 114 has been deposited over the integrated circuit 100, in accordance with some embodiments. The sacrificial gate layer 114 covers the fins 108. The sacrificial gate material can include materials that have a high etch selectivity with respect to the trench isolation regions 112. In an exemplary embodiment, the sacrificial gate layer 114 includes polysilicon. However, the sacrificial gate layer 114 may be a conductive, semiconductive, or non-conductive material and may be or include amorphous silicon, poly-crystalline silicon-germanium (poly-SiGe), metallic nitrides, metallic silicides, metallic oxides, and metals. The sacrificial gate layer 114 may be deposited by PVD, CVD, sputter deposition, or other techniques for depositing the selected material. As will be set forth in more detail below, the sacrificial gate layer 114 will eventually be patterned to form sacrificial gate structures.

FIG. 2 is a cross-sectional view of the integrated circuit 100 and at a same stage of processing as shown in FIG. 1, taken along cut lines 2 from FIG. 1, in accordance with some embodiments. FIG. 2 illustrates the semiconductor fin 108 extending in the X direction and including the stack 103 of semiconductor layers 104 and sacrificial semiconductor layers 106 formed over the substrate 102. The dielectric layer 109 is shown on a top surface of the fins 108 is a period the fin 108 is covered by the sacrificial gate layer 114.

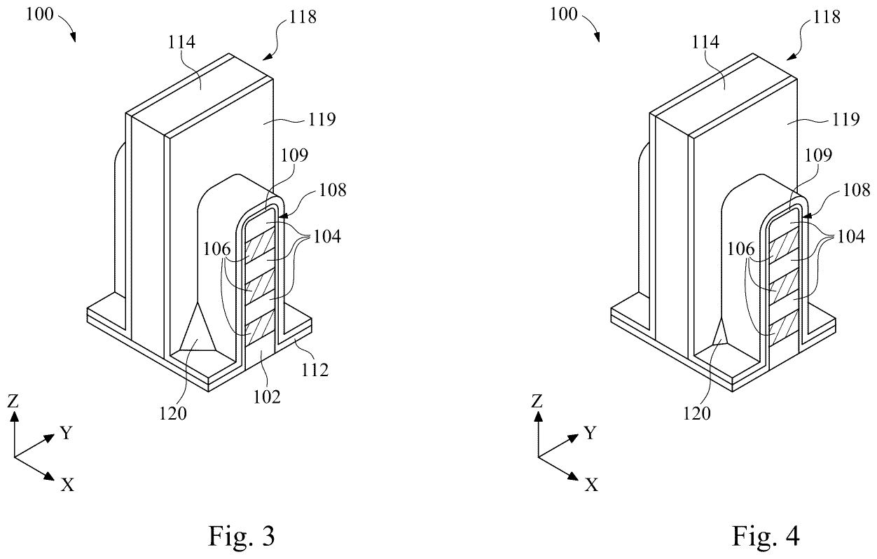

FIG. 3 is a perspective view of the integrated circuit 100 at an intermediate stage of processing, in accordance with some embodiments. In FIG. 3, sacrificial gate structures 118 have been formed over the fins 108. The sacrificial gate structures 118 extend in the Y direction, perpendicular to the fins 108. Each sacrificial gate structure 118 crosses multiple fins 108. The sacrificial gate structures 118 are also formed in the trenches 110. FIG. 3 illustrates only a single sacrificial gate structure 118. However, in practice, a plurality of sacrificial gate structures 118 are formed extending parallel to each other in the Y direction.

The sacrificial gate structures 118 include the sacrificial gate layer 114. In particular, the sacrificial gate structures 118 are formed by patterning the sacrificial gate layer 114 to form parallel strips or structures of the sacrificial gate layer 114 extending in the Y direction. As will be set forth in more detail below, the sacrificial gate structures 118 correspond to locations at which gate metals of transistors will be formed in subsequent steps. In particular, the sacrificial gate layer 114 will be removed and replaced with a gate metal.

Though not shown in FIG. 3, the sacrificial gate structures 118 can include a one or more dielectric mask layers formed on the sacrificial gate layer 114. The dielectric mask layers can include silicon nitride, silicon oxynitride, or other suitable dielectric materials. The dielectric mask layers can be deposited using CVD, ALD, PVD, or other suitable deposition processes. Other materials and deposition processes can be utilized for the dielectric layers and without departing from the scope of the present disclosure.

In FIG. 3, a byproduct layer 119 has been deposited on all exposed surfaces of the integrated circuit 100. In particular, the byproduct layer 119 covers the semiconductor fins 108, with the dielectric layer 109 interposed between the byproduct layer 119 and the semiconductor fins 108. The byproduct layer 119 covers side surfaces of the sacrificial gate layer 114. The byproduct layer is also on top of the trench isolation region 112.

In some embodiments, the byproduct layer 119 is a byproduct of the patterning process that forms the sacrificial gate structures 118. As described previously, the sacrificial gate structures 118 are formed by patterning the sacrificial gate layer 114 and the one or more dielectric mask layers formed on top of the sacrificial gate layer 114. The byproduct layer 119 may result from this patterning process. The byproduct layer 119 can include silicon, silicon oxide, SiO—Cl, SiO—HBr, SiO—N, SiO—Ar, or other materials.

In some embodiments, a byproduct accumulation 120 can form at a corner or junction where the trench isolation region 112, the fin 108, and the sacrificial gate layer 114 meet. The byproduct accumulation 120 corresponds to an accumulation of material of the byproduct layer 119 that is thicker than other portions of the byproduct layer 119. The byproduct accumulation 120 may include underlying material of the sacrificial gate layer 114. As will be set forth in more detail below, the presence of the byproduct accumulation 120 can result in significant problems in the final structure of the transistors formed from the fins 108.

Advantageously, embodiments of the present disclosure include utilization of an enhanced etching process to reduce or entirely remove the byproduct accumulation 120. The enhanced etching process can include a multistage etching process that first removes or greatly reduces the byproduct accumulation 120, and then subsequently entirely removes the byproduct layer 119, as can be seen in subsequent figures.

In some embodiments, the etching process includes a first plasma etching process that removes or reduces the byproduct accumulation 120. The plasma etching process can be performed in a plasma etching tool including a plasma etching chamber. Accordingly, at the stage of processing shown in FIG. 3, the wafer in which the integrated circuit 100 is formed is transported to a plasma etching chamber. The plasma etching process is then performed on the wafer including integrated circuit 100. The plasma etching process is an anisotropic etching process that selectively etches in a particular direction, as will be described in more detail below. The directional etching can enable removal or reduction of the byproduct accumulation 120.

During the plasma etching process, a plasma is generated within the plasma etching chamber. An etching gas can include HF, NH3, or other suitable etching gases. The plasma causes one or more of ions, neutral atoms, and radicals to travel from a glow region of the plasma in the selected direction with respect to the wafer. In some embodiments, the direction is substantially vertical. In some embodiments, the wafer is tilted so that the etching species impact the wafer from an angle with respect to vertical. This can be particularly beneficial in removing the byproduct accumulation 120.

In some embodiments, during the etching process a passivation gas is flowed into the etching chamber with the etching gas. The passivation gas can include N2, O2, CO2, or other suitable passivation gases. The passivation gases can assist in providing etch selectivity with respect to materials of the integrated circuit not to be etched. In some embodiments, a dilution gas is flowed into the plasma etching chamber. The dilution gas can include nonreactive gases such as He, Ar, N2, or other suitable gases.

In some embodiments, the plasma is generated by applying a voltage between a top electrode within the plasma etching chamber and a bottom electrode within the plasma etching chamber below the wafer. In some embodiments, a total power consumption of the plasma generation can be between 10 W and 40,000 W. In some embodiments, the pressure within the plasma etching chamber during the plasma etching process is between 1 mTorr and 800 mTorr. In some embodiments, the flow rate of the gases (etch, passivation, and dilution) can be between 20 sccm and 3000 sccm. Other etching gases, passivation gases, dilution gases, power levels, pressures, and flow rates can be utilized without departing from the scope of the present disclosure. While a plasma etching process has been described in relation to FIG. 3, in practice, other dry etching processes can be utilized to reduce or remove the byproduct accumulation 120, without departing from the scope of the present disclosure.

In FIG. 4, the initial portion of the etching processes been performed, as described in relation to FIG. 3. As can be seen in FIG. 4, the byproduct accumulation 120 has been substantially removed. The byproduct accumulation 120 may be entirely removed only partially removed. The benefits and consequences of this removal will be described further below.

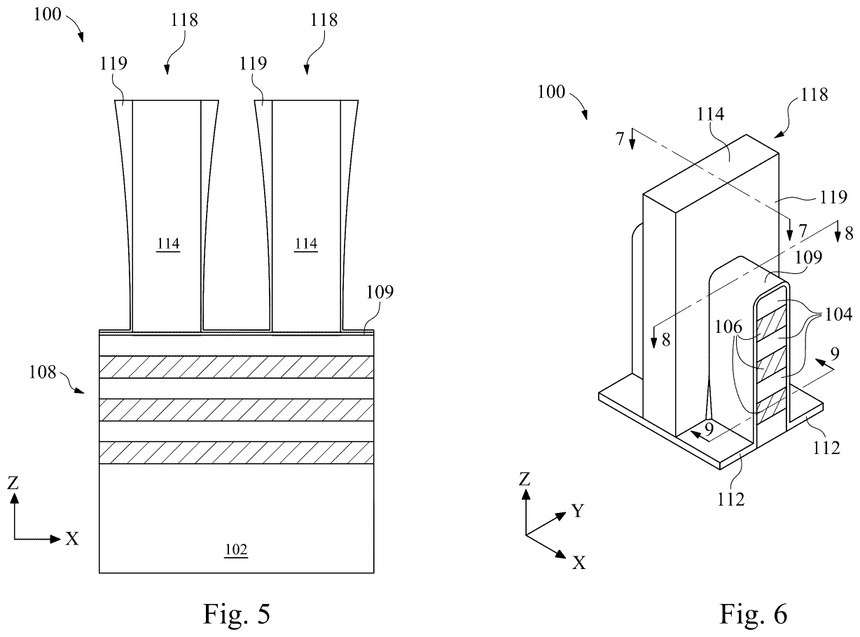

FIG. 5 is a cross-sectional view of the integrated circuit 100 at the stage of processing shown in FIG. 4, in accordance with some embodiments. FIG. 5 illustrates two sacrificial gate structures 118 crossing the semiconductor fin 108. A portion of the byproduct layer 119 still remains on sidewalls of the sacrificial gate structures 118. In practice, there may be more or less of the byproduct layer 119 remaining than is shown in FIG. 5 at the stage of processing.

In FIG. 6, a second portion of the etching process has been performed. The second portion of the etching process removes the remainder of the byproduct layer 119 from the exposed surfaces. The second etching process can include a wet etching process. The wet etching process can include an isotropic etching process that etches in all directions. The wet etching process selectively etches the byproduct material with respect to other exposed materials.

In some embodiments, after the plasma etching process has been performed, the wafer that includes the integrated circuit 100 is transferred from the plasma etching chamber to a wet etching chamber. In the wet etching chamber, the wet etches performed including exposing the integrated circuit 100 to a liquid chemical that etches the byproduct layer 119.

In some embodiments, the wet etching process does not substantially etch the dielectric layer 109. The result is the structure shown in FIG. 6. The byproduct layer 119 and the byproduct accumulation 120 have been removed. If only the wet etching process is performed, then a thick byproduct accumulation 120 may remain even after removal of all other portions of the byproduct layer 119. In some embodiments, a small accumulation of the material of the sacrificial gate layer 114 may remain in place of the byproduct accumulation 120.

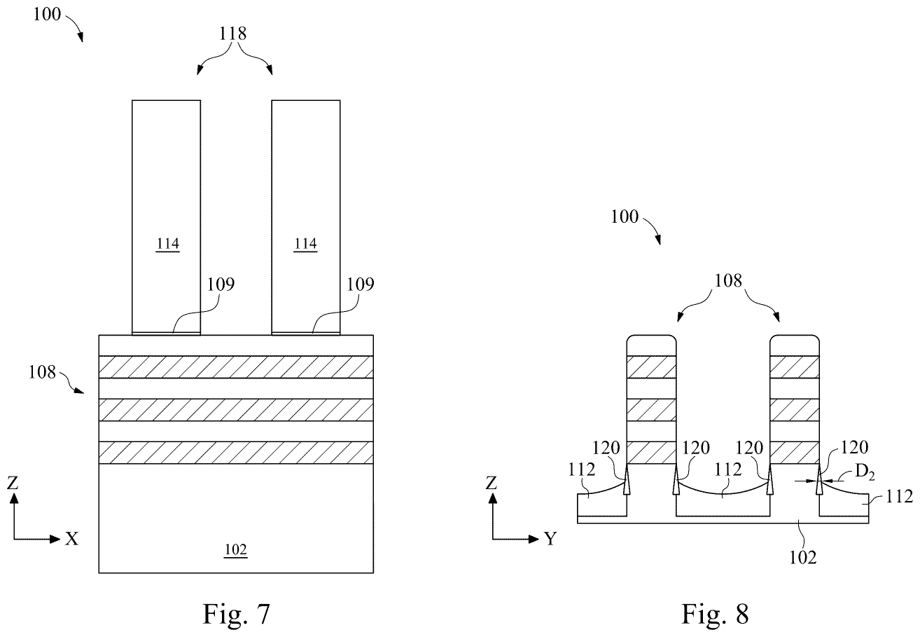

FIG. 7 is a cross-sectional view of the integrated circuit 100, taken along cut lines 7 of FIG. 6, in accordance with some embodiments. In FIG. 7, a third portion of the etching process has been performed. The third portion of the etching process removes the dielectric layer 109 (CESL) from all locations except directly below the sacrificial gate structures 118. This can be accomplished via a second wet etching process. In some embodiments, the dielectric layer 109 can be removed with the same wet etching process that removes the remainder of the byproduct layer 119.

FIG. 8 is a cross-sectional view of the integrated circuit 100 taken along the Y direction at a same stage of processing as in FIG. 7, taken along cut lines 8 from FIG. 6, in accordance with some embodiments. Two semiconductor fins 108 are shown in FIG. 8. FIG. 8 illustrates small remaining portions of the byproduct accumulation 120. The byproduct accumulation can correspond to the material of the byproduct layer 119 and/or material of the sacrificial gate layer 114.

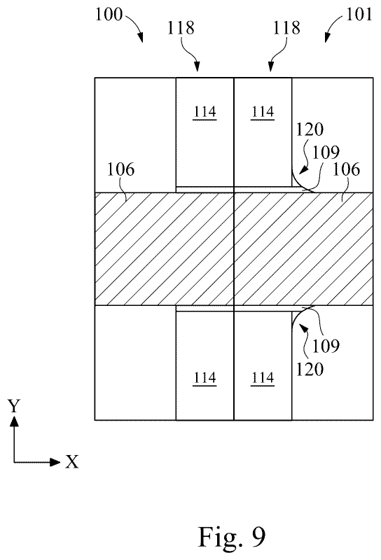

FIG. 9 is a cross-sectional view of the integrated circuit 100 taken in a horizontal plane along cut lines 9 from FIG. 6, but after removal of the exposed portions of the dielectric layer 109 in accordance with some embodiments. The cross-sectional view of FIG. 9 illustrates a portion corresponding to the integrated circuit 100, and a portion corresponding to an alternate integrated circuit 101.

In the alternate integrated circuit 101, the plasma etching process described in relation to FIGS. 3 and 4 is not performed. The result is that large amounts of byproduct accumulation 120 remain at the corner of the lowest sacrificial semiconductor layer 106 and the sacrificial gate structure 118. Furthermore, portions of the dielectric layer 109 (CESL) remain outside of the sacrificial gate structure 118. This can cause problems as will be described subsequently.

In integrated circuit 100, the byproduct accumulation 120 has been substantially removed because of the enhanced multistep etching process has been performed. Accordingly, the corners of the lowest sacrificial semiconductor layer 106 and the sacrificial gate structures 118 are sharp. In practice, a very small amount of the byproduct accumulation 120 may remain, but significantly reduced with respect to the alternate integrated circuit 101.

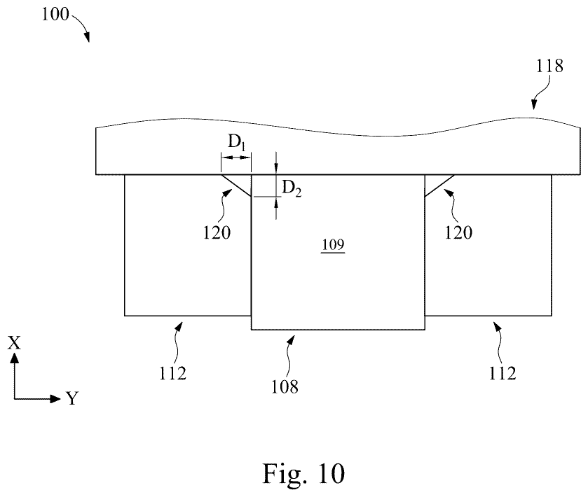

FIG. 10 is a top view of the integrated circuit 100, at the stage of processing shown in FIG. 6, in accordance with some embodiments. The top view of FIG. 6 illustrates that very little of the byproduct accumulation 120 remains after the enhanced etching process. In some embodiments, the remaining thickness of the byproduct accumulation 120 has a dimension D1 in the X direction between 0 nm and 2 nm. In some embodiments, the remaining thickness of the byproduct accumulation 120 in the Y direction has a dimension D2 between 0 nm and 2 nm. In the alternate integrated circuit 101, the dimensions D1 and D2 can be between 4 nm and 9 nm. The dimension D2 is also shown in FIG. 8.

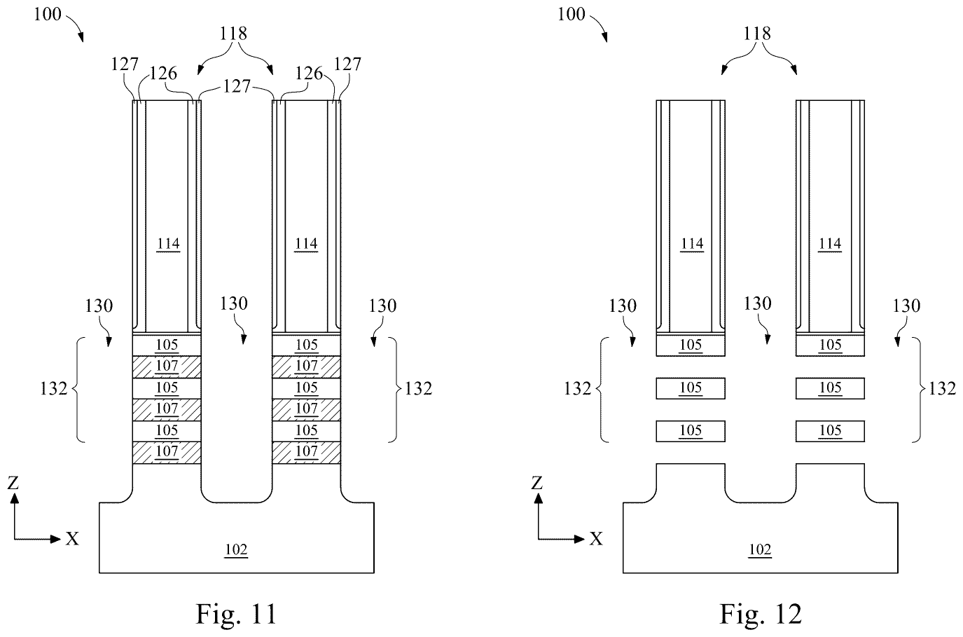

FIG. 11 is a cross-sectional view of the integrated circuit 100, in accordance with some embodiments. In FIG. 11, gate spacer layers 126 and 127 have been formed on the sidewalls of the sacrificial gate structures 118. The gate spacer layers 126 and 127 may also be formed on other exposed surfaces of the integrated circuit. For example, portions of the gate spacer layer 126 are formed on the top surfaces of the fins 108, on sidewalls of the fins 108, and on top surfaces of the shallow trench isolation regions 112. The gate spacer layer 126 can include one or more of SiO, SiN, SiON, SiCN, SiOCN, SiOC, or other suitable dielectric materials. The gate spacer layer 126 can be formed by PVD, CVD, ALD, or other suitable deposition processes. The gate spacer layer 127 can include one or more of SiO, SiN, SiON, SiCN, SiOCN, SiOC, or other suitable dielectric materials. The gate spacer layer 127 can be formed by PVD, CVD, ALD, or other suitable deposition processes.

After deposition of the gate spacer layers 126/127, portions (e.g., in the X-Y plane) of the gate spacer layers 126/127 have been removed. In other words, portions of the gate spacer layer that are on the top surfaces of the fins 108 and on the top surfaces of the shallow trench isolation regions 112 are removed. Vertically thicker portions of the gate spacer layers 126/127 remain on sidewalls of the fins 108. Removal of the portions of the gate spacer layer 126/127 can be accomplished via an anisotropic etching process, thereby exposing upper surfaces of the fins 108 and the trench isolation regions 112. After patterning of the gate spacer layers 126/127, vertically thicker portions of the gate spacer layers 126/127 remain, such as the portion shown in FIG. 11.

After removal of portions of the gate spacer layer 126/127, source/drain trenches 130 are formed in the fins 108. The sacrificial gate structures 118 and the gate spacer layers 126/127 are utilized as a mask for forming source/drain trenches 130 in the fins 108. In particular, one or more etching processes are performed to form the source/drain trenches 130 in the fins 108. Forming the source/drain trenches 130 includes etching through each of the semiconductor layers 104 and sacrificial semiconductor layers 106, and a portion of the substrate 102. Accordingly, the removal operations may include suitable etch operations for removing materials of the semiconductor layers 104, the sacrificial semiconductor layers 106, the substrate 102. The etching processes can include reactive ion etching (RIE), neutral beam etching (NBE), atomic layer etching (ALE), or the like.

Formation of the source/drain trenches 130 results in formation stacks 132 of channels 105. Each stack 132 of channels 105 corresponds to stacked channels of a transistor. Formation of the source/drain trenches 130 also results in formation of a plurality of sacrificial semiconductor nanostructures 107 from the sacrificial semiconductor layers 106. After formation of the source/drain trenches 130, the channels 105 and the sacrificial semiconductor nanostructures 107 may have substantially similar lateral dimensions.

FIG. 12 is a cross-sectional view of the integrated circuit 100, in accordance with some embodiments. In FIG. 12, the sacrificial semiconductor nanostructures 107 have been removed. The sacrificial semiconductor nanostructures 107 can be removed by performing an etching process that selectively etches the material of the sacrificial semiconductor nanostructures 107 with respect to the material of the channels 105. As described previously, in one exemplary embodiment, the channels 105 are silicon and the sacrificial semiconductor nanostructures 107 are silicon germanium. The etching process selectively etches the silicon germanium of the sacrificial semiconductor nanostructures 107 with respect to the silicon of the channels 105. The result is that the sacrificial semiconductor nanostructures 107 are entirely removed and the channels 105 remain. As described previously, other materials can be utilized for the channels 105 and the sacrificial semiconductor nanostructures 107 without departing from the scope of the present disclosure.

The view of FIG. 12 also illustrates that the source/drain trenches 130 extend into the substrate 102. In particular, the etching process that forms the source/drain trenches 130 also forms a recess in the substrate 102. As shown in FIG. 12, the recess may be concave.

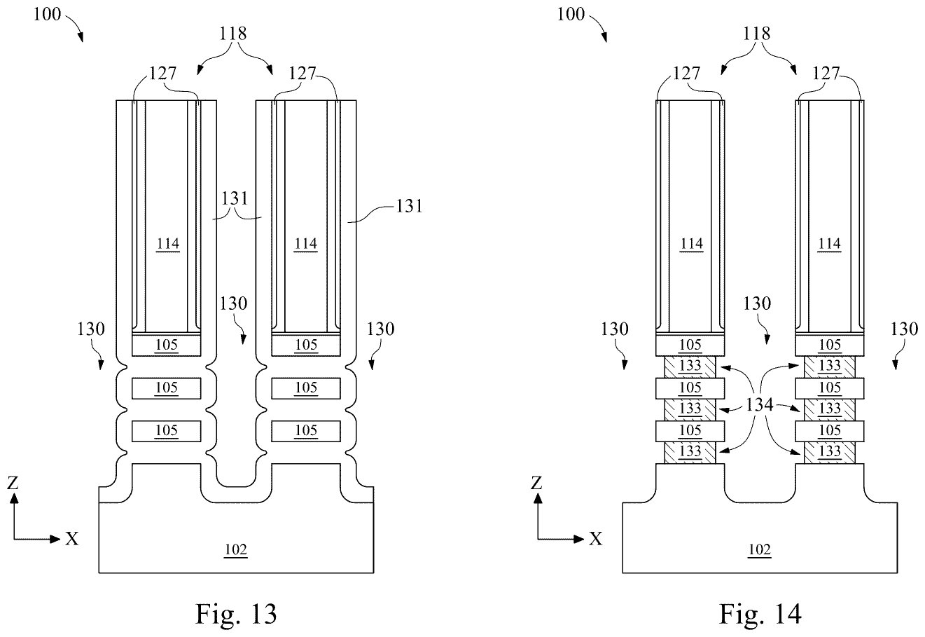

FIG. 13 is a cross-sectional view of the integrated circuit 100, in accordance with some embodiments. In FIG. 13, a dielectric layer 131 has been conformally deposited on the integrated circuit 100. The dielectric layer 131 is formed on sidewalls of the gate spacer layers 127, exposed portions of the substrate 102, and on exposed portions of the channels 105. Furthermore, the dielectric layer 131 fills the gaps between channels left by the removal of the sacrificial semiconductor nanostructures 107. In an exemplary embodiment, the dielectric layer 131 includes silicon oxide. Alternatively, the dielectric layer 131 can include, SiON, SiCN, SiOCN, SiOC, or other suitable dielectric materials. The dielectric layer 131 can be deposited by CVD, ALD, PVD, or other suitable deposition processes.

FIG. 14 is a cross-sectional view of the integrated circuit 100, in accordance with some embodiments. FIG. 14, sacrificial dielectric nanostructures 133 have been formed in place of the sacrificial semiconductor nanostructures 107. Accordingly, the sacrificial dielectric nanostructures 133 are formed between adjacent channels 105. The lowest sacrificial dielectric nanostructures 133 of each stack 132 is between the substrate 102 and the lowest channel 105 of each stack 132. The sacrificial dielectric nanostructures 133 are formed by performing an etching process of the dielectric layer 131 utilizing the gate spacer layers 127 as a mask. The etching process also forms recesses 134 in the dielectric nanostructures 133. In particular, an isotropic etching process is performed that selectively etches the material of the sacrificial dielectric nanostructures 133 with respect to other exposed materials. The etching process is timed so as to remove end portions of the sacrificial dielectric nanostructures 133 without entirely removing the sacrificial dielectric nanostructures 133. The result is that recesses 134 are formed in the dielectric nanostructures 133 between adjacent channels 105. In other words, the ends of the dielectric nanostructures 133 are recessed relative to the ends of the channels 105.

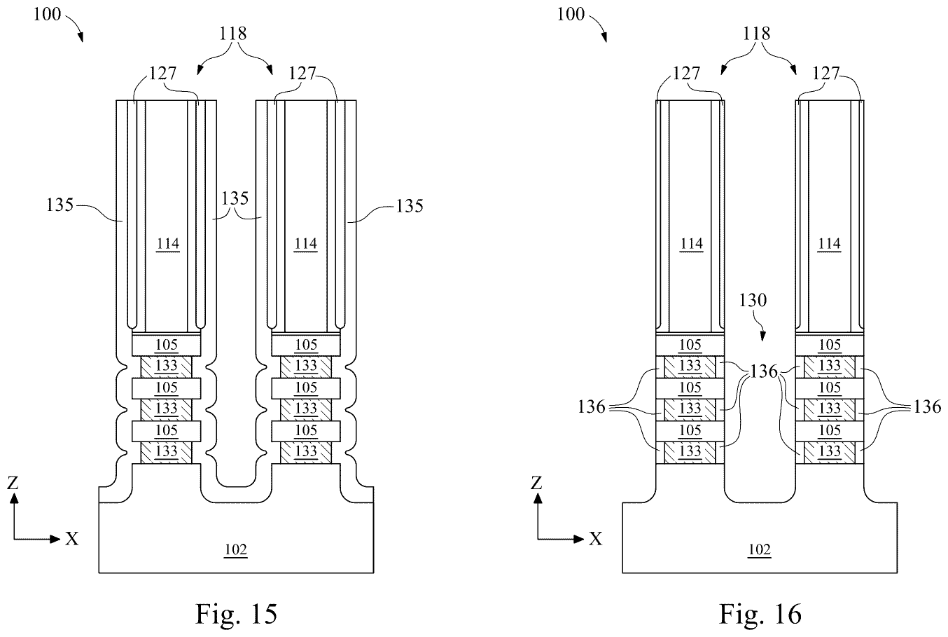

FIG. 15 is a cross-sectional view of the integrated circuit 100, in accordance with some embodiments. In FIG. 15, a dielectric layer 135 has been conformally deposited using ALD, CVD, or PVD. The dielectric layer that lines the gate spacer layers 127, lines the channels 105, the substrate 102, and fills the recesses 134. The dielectric layer 135 can include SiOCN, SiON, SiN, SiOC, SiOCN, SiON, or other suitable dielectric materials.

FIG. 16 is a cross-sectional view of an integrated circuit 100, in accordance with some embodiments. In FIG. 16, and etching processes been performed to remove the portions of the dielectric layer 135 outside of the recesses 136. The etching process can include an anisotropic etching process that selectively etches in the downward direction such that the gate spacer layer 127 and the channels 105 act as a mask for etching the dielectric layer 135. The result is that inner spacers 136 are formed.

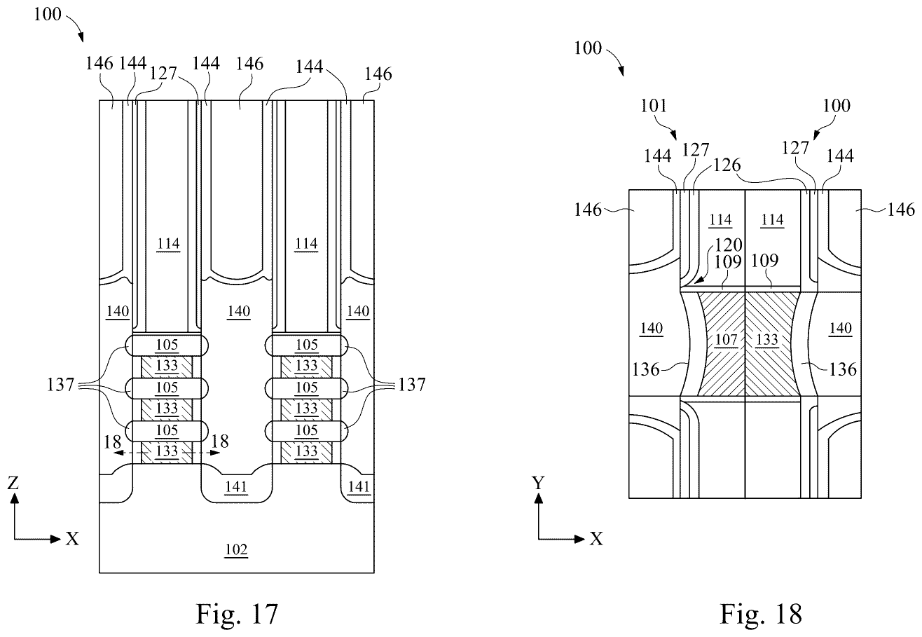

FIG. 17 is a cross-sectional view of the integrated circuit 100, in accordance with some embodiments. Semiconductor structures 137 have been formed on the ends of the channels 105. In particular, an epitaxial growth process has been performed to grow the semiconductor structures 137 from the channels 105. In an exemplary embodiment, the semiconductor structures 137 include silicon germanium. However, other semiconductor materials can be utilized without departing from the scope of the present disclosure. In practice, after the epitaxial growth process to form the semiconductor structures 137, the semiconductor material extends into the source/drain trenches 130.

A bottom semiconductor layer 141 has been formed in the bottom of the trenches 130 in the concave recesses formed in the substrate 102. The bottom semiconductor layer 141 can include intrinsics semiconductor material such as undoped silicon, undoped silicon germanium or other semiconductor materials. FIG. 2B, in some embodiments, the bottom semiconductor layer 140 one can instead be a bottom dielectric structure that electrically isolates subsequently formed source/drain regions from the substrate 102. The bottom dielectric structures can include silicon oxide, silicon nitride, or other suitable dielectric materials.

In FIG. 17, source/drain regions 140 have been formed. In the illustrated embodiment, the source/drain regions 140 are epitaxially grown from the semiconductor structures 137 and, if present, the bottom semiconductor layer 141. The source/drain regions 140 fill the source/drain trenches 130. For each stack 132 of channels 105, there are two source/drain regions 140. Each channel 105 of a stack 132 extends between adjacent source/drain regions 140.

In some embodiments, some stacks 132 of channels 105 may share a source/drain 140 with a stack 132 of channels 105 that is adjacent in the X direction. This is the case for the central source/drain region 140 of FIG. 17, which is shared by the two stacks of channels 105 on either side.

The source/drain regions 140 may include any acceptable material, such as appropriate for n-type or p-type devices. For n-type devices, the source/drain regions 140 include materials exerting a tensile strain in the channel regions, such as silicon, SiC, SiCP, SiP, or the like, in some embodiments. When p-type devices are formed, the source/drain regions 140 include materials exerting a compressive strain in the channel regions, such as SiGe, SiGeB, Ge, GeSn, or the like, in accordance with certain embodiments. The source/drain regions 140 may have surfaces raised from respective surfaces of the fins and may have facets.

The source/drain regions 140 may be implanted with dopants followed by an annealing process. The source/drain regions 140 may have an impurity concentration of between about 10¹⁹ cm⁻³ and about 10²¹ cm⁻³. N-type and/or p-type impurities for source/drain regions 140 may be any of the impurities previously discussed. In some embodiments, the source/drain regions 140 are in situ doped during growth.

In FIG. 17, a CESL 144 and an interlevel dielectric (ILD) 146 have been formed. The CESL layer 144 can include a thin dielectric layer conformally deposited on exposed surfaces of the source/drain regions 140, the trench isolation region 112, the gate spacer layer 127, and on other exposed surfaces. The CESL layer 144 can include SiN, SiC, SiOC, SiOCN, SiON, or other suitable dielectric materials. The CESL 144 can be deposited by CVD, ALD, PVD, or other suitable deposition processes.

The dielectric layer 146 covers the CESL 144. The dielectric layer 146 can include SiO, SiON, SiN, SiC, SiOC, SiOCN, SiON, or other suitable dielectric materials. The dielectric layer 146 can be deposited by CVD, ALD, PVD, or other suitable deposition processes.

FIG. 18 includes a right-hand portion that is a cross-sectional view of the integrated circuit 100 of FIG. 17, and a left hand portion this is a cross-sectional view of the alternate integrated circuit 101, in accordance with some embodiments. The right-hand portion of FIG. 18 corresponds to the horizontal plane of the X and Y axes taken through the lowest sacrificial dielectric nanostructures 133. FIG. 18 again shows a portion of the integrated circuit 100 and a portion of the alternate integrated circuit 101, in a similar manner as described in relation to FIG. 9.

As described previously, in the alternate integrated circuit 101, the enhanced etching process is not performed and, accordingly, the byproduct accumulation 120 protrudes and extends close to the source/drain region 140. This can be dangerous as, after the sacrificial gate layer 114 is replaced with a gate metal, the gate metal will be very close to the source/drain region 140 and could even for me short-circuit. However, as can be seen in the integrated circuit 100, there is little or no byproduct accumulation and the sacrificial gate layer 114 does not protrude significantly toward the source/drain region 140.

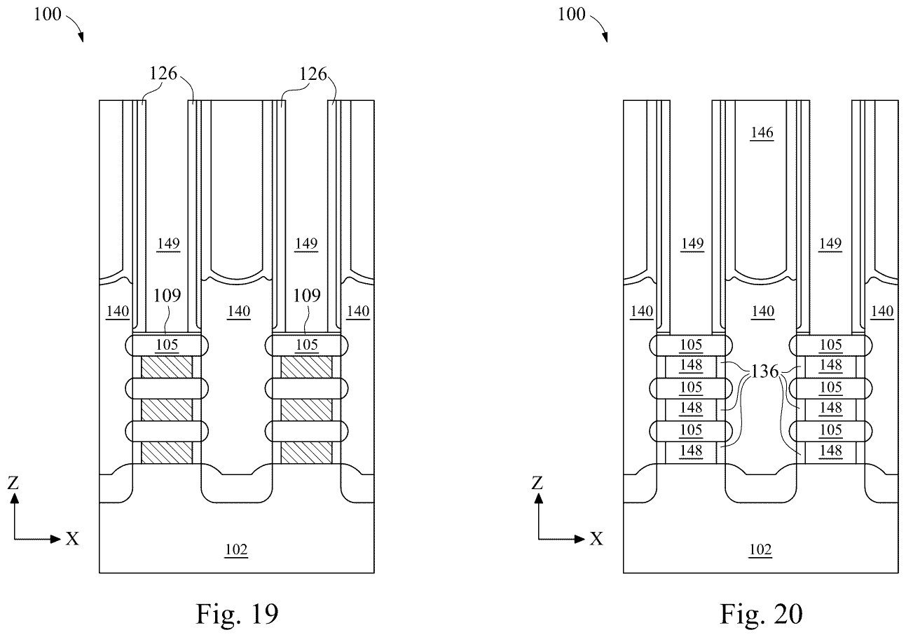

FIG. 19 is a cross-sectional view of the integrated circuit 100, in accordance with some embodiments. FIG. 19, the sacrificial gate structures 118 have been removed from between the gate spacer layers 126. In particular, the sacrificial gate layer 114 has been entirely removed from between the gate spacer layers 126.

In some embodiments, the sacrificial gate layer 114 is removed by an anisotropic dry etching process. For example, the etching process may include a dry etch process using reaction gases that selectively etch the sacrificial gate layer 114 without etching the spacer layer 126. The dielectric layer 109, when present, may be used as an etch stop layer when the sacrificial gate layer 114 is etched. The dielectric layer 109 may then be removed after the removal of the sacrificial gate layer 114.

Removal of the sacrificial gate layer 114 results in the formation of a void 149 between the gate spacer layers 126 above the channels 105. As will be set forth in more detail below, an upper portion of a gate metal or gate electrode will be formed in the void 149. Accordingly, the sacrificial gate layer 114 is sacrificial in the sense that the upper portion of the gate metal will eventually be formed in its place.

FIG. 20 is a cross-sectional loom the integrated circuit 100, in accordance with some embodiments. In FIG. 20, the channels 105 are released by removal of the sacrificial dielectric nanostructures 133. The sacrificial dielectric nanostructures 133 can be removed by a selective etching process using an etchant that is selective to the material of the sacrificial dielectric nanostructures 133, such that the sacrificial dielectric nanostructures 133 are removed without substantially etching the channels 105 or the semiconductor structures 137. Removal of the sacrificial dielectric nanostructures 133 results in the formation of voids 148 between the channels 105.

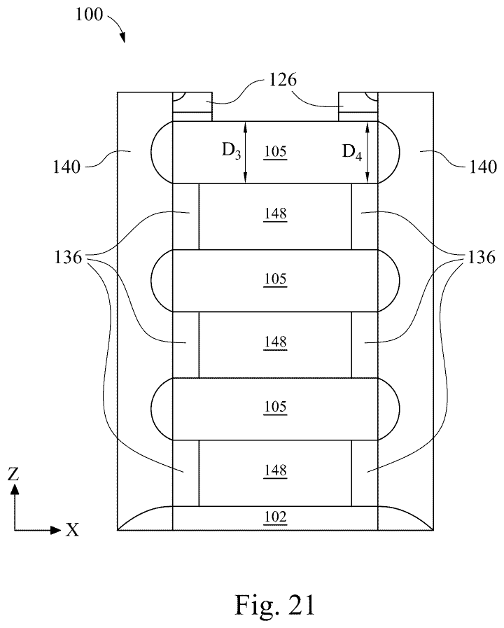

FIG. 21 is an enlarged cross-sectional view of a portion of the integrated circuit 100 at the stage of processing of FIG. 20, in accordance with some embodiments. The enlarged view illustrates the channels 105, the voids 148, the inner spacers 136, and the source/drain regions 140. One benefit of the process shown herein, is that each of the channels 105 has a substantially constant vertical thickness. For example, a thickness dimension D3 near center of the channel 105 is substantially the same as the thickness dimension D4 near a lateral end of the channel 105. In other possible solutions, it is possible that the channels 105 can be substantially etched during release of the channels 105. However, because release of the channels 105 includes removing the sacrificial dielectric nanostructures 133 that have a very high etch selectivity with respect to the channels 105, the channels 105 are not substantially etched. The result is that the thickness D3 is different from the fitness D4 by less than 0.5 nm. The result is that the overall resistance of the stacked channels 105 during operation of the transistor is relatively low, resulting in fewer losses. This improves the DC performance of the transistors. In some embodiments, the dimension D3 is between 9 nm and 10 nm, though other thicknesses can be utilized without departing from the scope of the present disclosure.

In some embodiments, the channels 105 all have a same thickness. In other words, the lower channel 105, the central channel 105, and the top channel 105 of each stack 132 all have a substantially equal vertical thickness. Additionally, the voids 148 all have a substantially equal vertical thickness. The result is that subsequently formed gate metals will have a same thickness between channels 105.

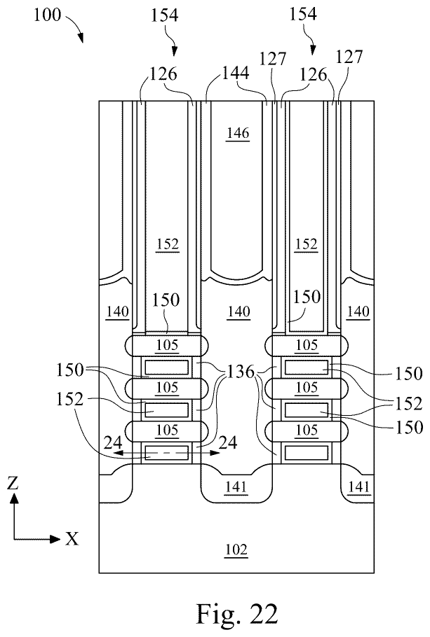

FIG. 22 is a cross-sectional view of the integrated circuit 100, in accordance with some embodiments. In FIG. 22, a high-K dielectric layer 150 and a gate metal 152 have been formed, in accordance with some embodiments. Though not shown in FIG. 22, an interfacial dielectric layer may be formed prior to formation of the high K dielectric layer 150. The interfacial dielectric layer and the high K dielectric layer 150 corresponds to a gate dielectric of the transistors.

The interfacial gate dielectric layer is deposited on all exposed surfaces of the channels 105. The interfacial gate dielectric layer is wrapped around the channels 105. The interfacial gate dielectric layer can include a dielectric material such as silicon oxide, silicon nitride, or other suitable dielectric materials. The interfacial gate dielectric layer can include a comparatively low-K dielectric with respect to high-K dielectric such as hafnium oxide or other high-K dielectric materials that may be used in gate dielectrics of transistors. High-K dielectrics can include dielectric materials with a dielectric constant higher than the dielectric constant of silicon oxide. The interfacial gate dielectric layer can be formed by a thermal oxidation process, a chemical vapor deposition (CVD) process, or an atomic layer deposition (ALD) process. The interfacial gate dielectric layer can have a thickness between 0.5 nm and 2 nm. Other materials, deposition processes, and thicknesses can be utilized for the interfacial gate dielectric layer without departing from the scope of the present disclosure.

The high-K dielectric layer 150 is deposited in a conformal deposition process. The conformal deposition process deposits the high-K dielectric layer 150 on the interfacial gate dielectric layer, on the substrate 102, on the trench isolation regions 112, and on the gate spacer layers 126. The high-K gate dielectric layer 150 is wrapped around the channels 105. The high-K gate dielectric layer 150 has a thickness between 1 nm and 3 nm. The high-K dielectric layer includes one or more layers of a dielectric material, such as HfO₂, HfSiO, HfSiON, HfTaO, HfTiO, HfZrO, zirconium oxide, aluminum oxide, titanium oxide, hafnium dioxide-alumina (HfO₂—Al₂O₃) alloy, other suitable high-K dielectric materials, and/or combinations thereof. The high-K dielectric layer 150 may be formed by CVD, ALD, or any suitable method. Other thicknesses, deposition processes, and materials can be utilized for the high-K dielectric layer 150 without departing from the scope of the present disclosure. The high-K dielectric layer 150 is a gate dielectric layer.

The gate metal 152 is deposited on all exposed surfaces of the high-K dielectric layer 150. The gate metal 152 is wrapped around the channels 105. Although the gate metal 152 is shown as a single layer in FIG. 22, in practice, the gate metal 152 can include one or more conductive liner layers, work function layers, and gate fill layers that collectively make up the gate metal. The gate metal can include one or more of Ti, TiN, Ta, TaN, Al, Cu, Co, Ru, W, Au, or other suitable conductive materials. The gate metal 152 can be deposited by PVD, ALD, or CVD. Other configurations, materials, and deposition processes can be utilized for the gate metal 152 without departing from the scope of the present disclosure.

At the stage of processing shown in FIG. 22, the transistors 154 are substantially complete. Each transistor 154 includes a stack 132 of channels 105 extending between the source/drain regions 140 and acting as stacked channels of the transistor 154. The gate metal 152 acts as a gate electrode surrounding the channels 105. Though not shown in FIG. 22, source/drain contacts may also be formed. Trenches can be formed in the dielectric layers 144 and 146 to expose the top surfaces of the source/drain regions 140. A silicide may be formed on the exposed portions of the source/drain regions 140. The conductive via or plug can be formed in contact with the silicide. The voltages can be applied to source/drain regions 140, or currents can be passed via the source/drain contacts.

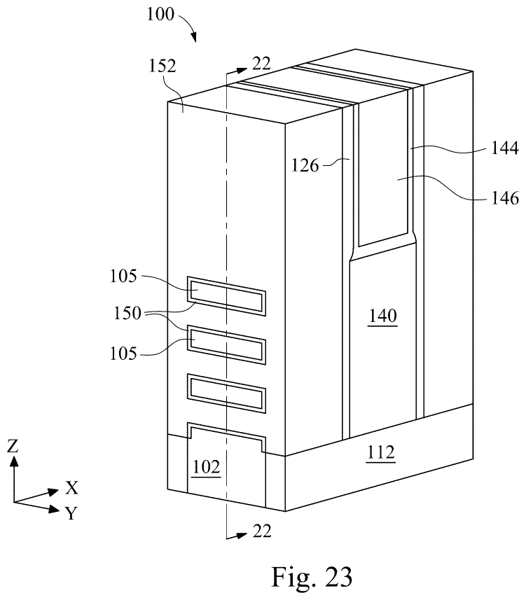

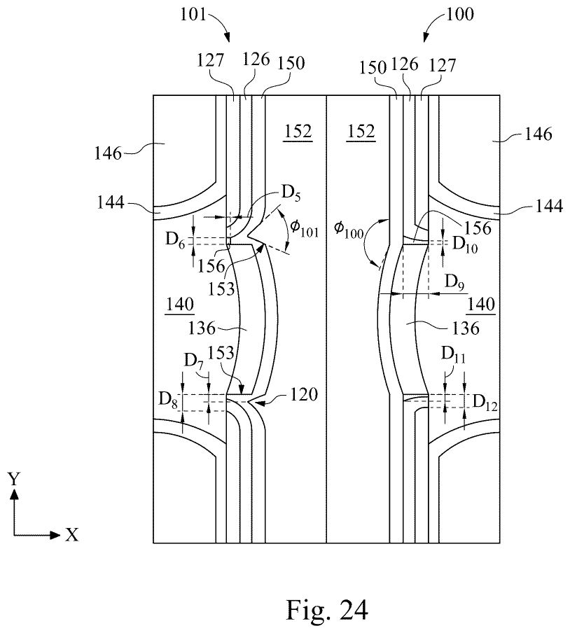

FIG. 23 is a perspective view of the integrated circuit 100 at the stage of processing shown in FIG. 22, in accordance with some embodiments. The view of FIG. 22 is taken along cut lines 22 from FIG. 23.

FIG. 24 includes a right-hand portion that is a cross-sectional view of the integrated circuit 100 of FIG. 22, and a left hand portion this is a cross-sectional view of the alternate integrated circuit 101, in accordance with some embodiments. FIG. 24 is a cut taken through the gate metal 152 below the lowest channel 105, similar to the location of the cuts for FIGS. 9 and 18 however, in FIG. 24, the sacrificial gate layer 114 has been replaced with the gate metal 152 and the high K dielectric layer 150. FIG. 24 again illustrates the integrated circuit 100 in accordance with some embodiments, in the alternate integrated circuit 100 that did not utilize the enhanced etching process.

In the integrated circuit 101, the byproduct accumulation 120 has resulted in a protrusion 153 of the gate metal 152 and the high K dielectric layer 150 toward the source/drain region 140. The protrusion 153 is substantially not present the corresponding bend in the high K dielectric 150 at the edge of the inner spacer 136 is an angle θ101. In some embodiments, the angle θ101 is between 80° and 100° for the bottom gate metal portion (portion below the lowest channel 104), between 100° and 130° for the middle gate metal portion (portion between the lowest channel 105 and the middle channel 105), and between 160° and 180° for the upper gate metal portion (between the middle channel 105 and the top channel 105).

At the protrusion 153, the high K dielectric layer 150 meets a thin native oxide layer 156 and is separated from the source/drain region 140 by a relatively small distance D5, between 0.3 nm and 3 nm. The native oxide layer 156 has a dimension D6 in the Y direction between 3 nm and 5 nm. In some embodiments. The dimension D7 is between 3 nm and 5 nm. The dimension D8 is between 8 nm and 13 nm. Though not shown in FIG. 18, the native oxide layer 156 may also be present in FIG. 18.

Conversely, in the integrated circuit 100 there is little or no protrusion of the gate metal 152 and the high K dielectric layer 150 toward the source/drain region 140 at the edge of the inner spacer 136. In some embodiments, the high K dielectric layer makes an angle θ100 at the edge of the inner spacer 136. For the lowest portion of the gate metal 152, θ 100 has a value between 150° and 165°. For the middle portion of the gate metal, θ 100 is between 165° and 170°. For the upper portion of the gate metal, θ 100 is between 170° and 180°. The values of these angles are highly beneficial because they result in gate metals 152 that do not include sharp protrusions toward the source/drain regions 140 that could result in high leakage currents or even short circuits. Accordingly, the high values of the angles result in improved electrical performance of transistors.

Furthermore, the dimension D9 corresponds to the separation of the high K dielectric layer 150 and the source/drain region 140 and has a minimum value between 5 nm and 10 nm. This value is highly beneficial because it helps ensure that there is little or no leakage between the gate metal and the source/drain regions. This also reduces parasitic capacitances. The overall result is improved performance of transistors. Accordingly, an integrated circuit 100, the possibility of short circuit between the source/drain region 140 and the gate metal 152 is greatly reduced, as is the capacitance between the gate metal 152 and the source/drain region 140. Additionally, the dimension D10 corresponds to a thickness of the native oxide layer 156 and is between 0.3 nm and 1 nm. The dimension D11 is between 0.3 nm and 1 nm. The dimension D12 is between 5 nm and 8 nm. These values all combine to result in transistors with improved electrical performance.

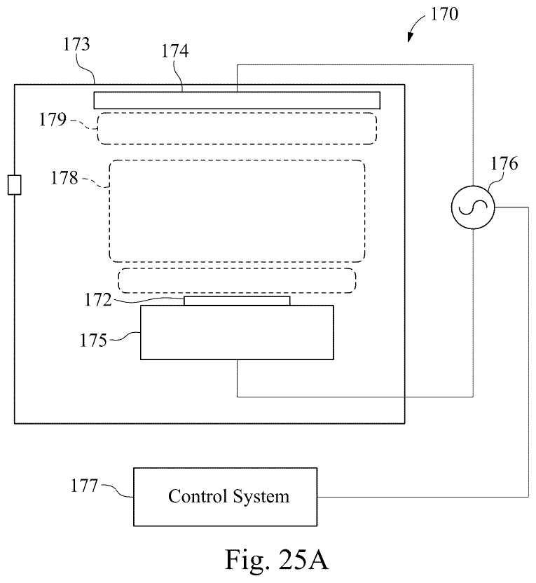

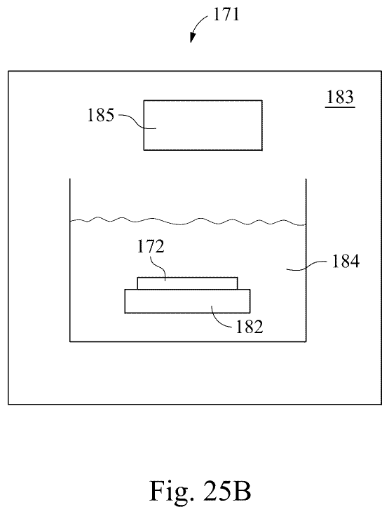

FIG. 25A is an illustration of a plasma etching tool 170, according to some embodiments. FIG. 25B is an illustration of a wet etching tool 171, in accordance with some embodiments. In some embodiments, a wafer 172 (including the integrated circuit 100) is transferred to the plasma etching tool 170 at the stage of processing shown in FIG. 3. The plasma etching process is then performed as described in relation to FIGS. 3 and 4 to remove the byproduct accumulation 120. The wafer 172 (including integrated circuit 100) is then transferred to the wet etching tool 171. The wet etching processes is then performed to remove the byproduct layer 119, as described previously.

The plasma etching tool 170 includes a semiconductor process chamber 173 including a top electrode 174, a bottom electrode 175, and a wafer 172 positioned on the bottom electrode 175. A radiofrequency power source 176 is coupled to the top electrode 174 and the bottom electrode 175. The control system 177 is coupled to the radiofrequency power source 176. The bottom electrode 175 can also be a chuck configured to hold the wafer 172.

In one embodiment, the radiofrequency power source 176 drives the top electrode 174 and the bottom electrode 175 to generate a plasma in the plasma region 178 by applying an AC voltage in a radio frequency range between the top electrode 174 and the bottom electrode 175. The plasma can be generated from the gasses within the semiconductor process chamber 173, as described previously.

A glow discharge is associated with the plasma region 178. For example, etching processes, implantation processes, deposition processes, and other types of plasma-assisted semiconductor processes result in the plasma and in particular optical and thermal characteristics. The glow discharge can also depend on various process parameters such as DC voltage, radiofrequency power, pressure, temperature, etc.

In the example of FIG. 25A, the plasma generation process results in an anode glow region 179 adjacent to the top electrode 174. In this example, the top electrode 174 is the anode. The plasma generation process also results in a cathode glow region 180 adjacent to the bottom electrode cathode. In this example, the bottom electrode 175 is the cathode. The main plasma region 178 is positioned between the anode glow region 179 and the cathode glow region 180. Etching particles are driven vertically downward to etch features of the wafer 172 selectively in the downward direction, as described previously. In some embodiments, the wafer 172 can be held on a chuck that can be tilted or rotated to enable etching particles to impact features of the wafer at a selected angle, as described previously. In these cases, the bottom electrode may be configured other than shown in FIG. 25A.

FIG. 25B is a simplified illustration of a wet etching tool 171, in accordance with some embodiments. The wafer 172 is transferred to the wet etching tool after the plasma etching process has been performed. The wet etching tool includes an interior etching chamber 183. The wafer 172 is placed on a wafer support 182 in an etching bath 184. Various etching equipment 185 may also be utilized to assist in performing the wet etching process. As described previously, the wet etching process can be utilized in conjunction with the processes described in relation to FIGS. 4-8. Other types of wet etching tools 171 can be utilized without departing from the scope of the present disclosure.

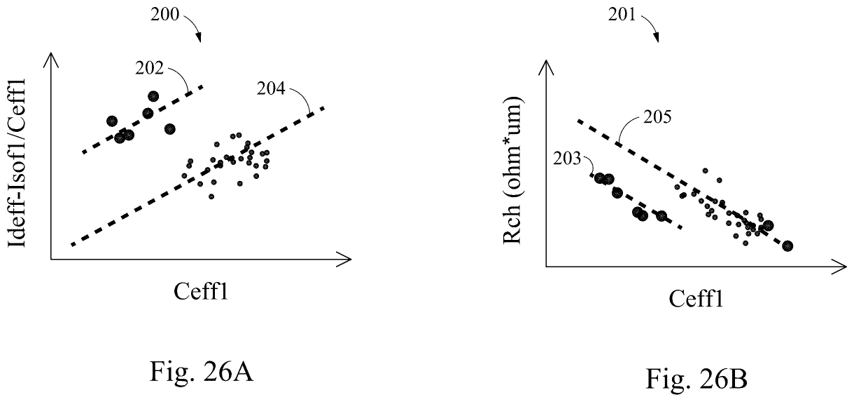

FIG. 26A is a graph 200 illustrating drain effective current minus the source effective current vs Ceff1 for transistors, in accordance with some embodiments. The curve 202 corresponds to a device in which the multistep etching process has been performed and in which the sacrificial dielectric nanostructures 133 have been utilized in place of the sacrificial semiconductor nanostructures 107. The curve 204 corresponds to a device in which the sacrificial dielectric nanostructures 133 are not utilized. As can be seen, the DC/AC characteristics of transistors are greatly improved in the curve 202. When Ceff is smaller, the current is larger. Therefore, the drain effective current is deducted the current source (Sof1) that would be better. Better DC indicates a smaller resistance R. Better AC means small Ceff.

FIG. 26B is a graph 201 illustrating the overall channel resistance vs Ceff1 for transistors, in accordance with some embodiments. The curve 203 corresponds to a device in which the multistep etching process has been performed and in which the sacrificial dielectric nanostructures 133 have been utilized in place of the sacrificial semiconductor nanostructures 107. The curve 205 corresponds to a device in which the sacrificial dielectric nanostructures 133 are not utilized. As can be seen, the overall channel resistance of transistors is reduced in the curve 203.

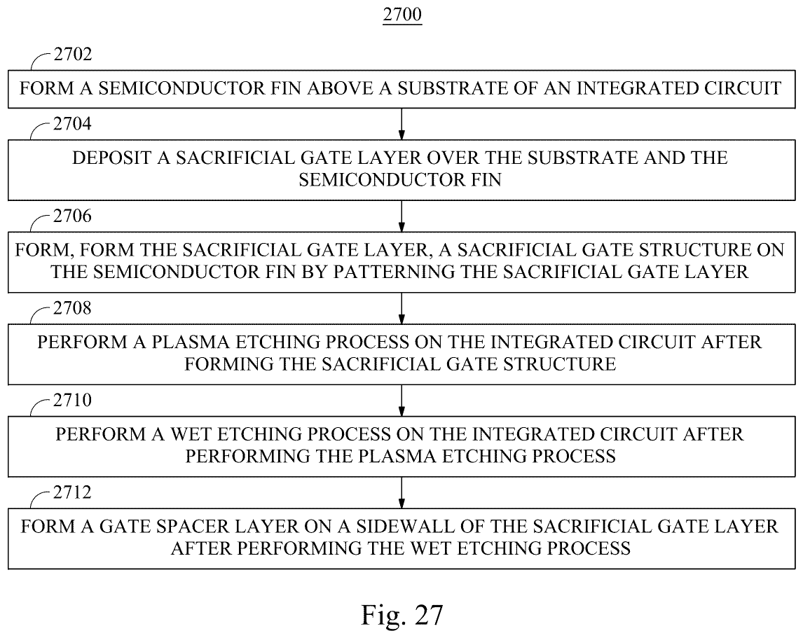

FIG. 27 is a flow diagram of a method 2700 for forming an integrated circuit, in accordance with some embodiments. The method 2700 can utilize the structures, processes, and systems described in relation to the other Figures. At 2702, the method 2700 includes forming a semiconductor fin above a substrate of an integrated circuit. One example of a semiconductor fin is the semiconductor fin 108 of FIG. 1. One example of a substrate is the substrate 102 of FIG. 1. At 2704, the method 2700 includes depositing a sacrificial gate layer over the substrate and the semiconductor fin. One example of a sacrificial gate layer is the sacrificial gate layer 114 of FIG. 1. At 2706, the method 2700 includes forming, from the sacrificial gate layer, a sacrificial gate structure on the semiconductor fin by patterning the sacrificial gate layer. One example of a sacrificial gate structure is the sacrificial gate structure 118 of FIG. 3. At 2708, the method 2700 includes performing a plasma etching process on the integrated circuit after forming the sacrificial gate structure. At 2710, the method 2700 includes performing a wet etching process on the integrated circuit after performing the plasma etching process. At 2712, the method 2700 includes forming a gate spacer layer on a sidewall of the sacrificial gate layer after performing the wet etching process. One example of a gate spacer layer is the gate spacer layer 126/127 of FIG. 11.

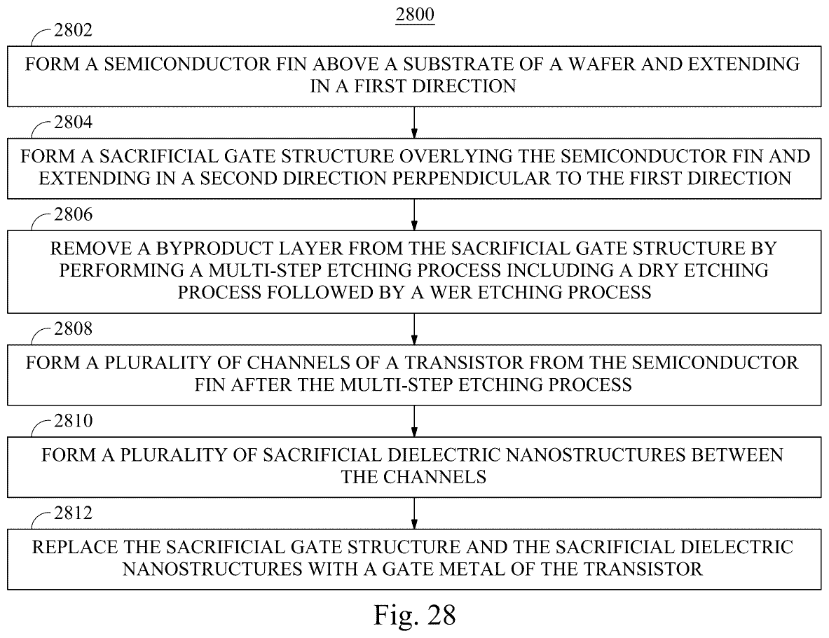

FIG. 28 is a flow diagram of a method 2800 for forming an integrated circuit, in accordance with some embodiments. The method 2800 can utilize the structures, processes, and systems described in relation to the other Figures. At 2802, the method 2800 includes forming a semiconductor fin above a substrate of a wafer and extending in a first direction. One example of a semiconductor fin is the semiconductor fin 108 of FIG. 1. One example of a substrate is the substrate 102 of FIG. 1. At 2804, the method 2800 includes forming a sacrificial gate structure overlying the semiconductor fin and extending in a second direction perpendicular to the first direction. One example the sacrificial gate structure is the sacrificial gate structure 118 of FIG. 3. At 2806, the method 2800 includes removing a byproduct layer from the sacrificial gate structure by performing a multi-step etching process including a dry etching process followed by a wet etching process. One example of a byproduct layer is the byproduct layer 119 of FIG. 3. At 2808, the method 2800 includes forming a plurality of channels of a transistor from the semiconductor fin after the multi-step etching process. One example of channels are the channels 105 of FIG. 11. At 2810, the method 2800 includes forming a plurality of sacrificial dielectric nanostructures between the channels. One example of sacrificial dielectric nanostructures are the sacrificial dielectric nanostructures 133 of FIG. 14. At 2812, the method 2800 includes replacing the sacrificial gate structure and the sacrificial dielectric nanostructures with a gate metal of the transistor. One example of a gate metal is the gate metal 152 of FIG. 22.

Embodiments of the disclosure provide a method of forming transistors that results in improved transistor characteristics. A plurality of semiconductor fins are formed above a substrate extending in a first direction. A plurality of sacrificial gate structures are formed extending in a second direction and overlying the semiconductor fins. Patterning of the sacrificial gate structures results in a byproduct layer covering the sacrificial gate structures in the semiconductor fins. More particularly, a thick accumulation of the byproducts may collect at bottom junctions between semiconductor fins and sacrificial gate structures. Embodiments of the present disclosure advantageously utilize a multistep etching process including a combination of a dry etch and a wet etch to effectively remove the byproduct layer and the thick accumulation. Additionally, sacrificial dielectric nanostructures are utilized to release the channels of gate all around transistors formed in conjunction with the fins. The result of these processes is that uniform channel thickness is maintained and gate metals do not include protrusions that risk leakage or shorting with source/drain regions. Transistor performance is greatly improved, as are wafer yields. More particularly, channel resistance is reduced and AC/DC performance of transistors is improved.

In some embodiments, a method includes forming a semiconductor fin above a substrate of an integrated circuit and depositing a sacrificial gate layer over the substrate and the semiconductor fin. The method includes forming, from the sacrificial gate layer, a sacrificial gate structure on the semiconductor fin by patterning the sacrificial gate layer and performing a plasma etching process on the integrated circuit after forming the sacrificial gate structure. The method includes performing a wet etching process on the integrated circuit after performing the plasma etching process and forming a gate spacer layer on a sidewall of the sacrificial gate layer after performing the wet etching process.

In some embodiments, a method includes forming a semiconductor fin above a substrate of a wafer and extending in a first direction and forming a sacrificial gate structure overlying the semiconductor fin and extending in a second direction perpendicular to the first direction. The method includes removing a byproduct layer from the sacrificial gate structure by performing a multi-step etching process including a dry etching process followed by a wet etching process and forming a plurality of channels of a transistor from the semiconductor fin after the multi-step etching process. The method includes forming a plurality of sacrificial dielectric nanostructures between the channels and replacing the sacrificial gate structure and the sacrificial dielectric nanostructures with a gate metal of the transistor.

In some embodiments, a device includes a substrate and a transistor. The transistor includes a plurality of stacked channels above the substrate, an inner spacer between a bottom channel of the stacked channels and the substrate, a gate spacer layer, and a gate dielectric layer in contact with the inner spacer and the gate spacer layer at junction of the gate spacer layer and the inner spacer layer. The transistor includes a gate metal wrapped around the channels and in contact with the gate dielectric between the substrate and the bottom channel. The inner spacer layer bends, in a lateral plane, at the junction with an angle between 150 degrees and 180 degrees.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming a semiconductor fin above a substrate of an integrated circuit;
depositing a sacrificial gate layer over the substrate and the semiconductor fin;
forming, from the sacrificial gate layer, a sacrificial gate structure on the semiconductor fin by patterning the sacrificial gate layer;
performing a plasma etching process on the integrated circuit after forming the sacrificial gate structure;
performing a wet etching process on the integrated circuit after performing the plasma etching process; and
forming a gate spacer layer on a sidewall of the sacrificial gate layer after performing the wet etching process.

2. The method of claim 1, wherein patterning the sacrificial gate layer results in a byproduct layer on sidewalls of the sacrificial gate layer, on sidewalls of the semiconductor fin, and on a trench isolation region adjacent to the semiconductor fin and the sacrificial gate structure.

3. The method of claim 2, wherein performing the plasma etching process includes at least partially removing a byproduct accumulation at a corner where the semiconductor fin, the sacrificial gate structure, and the trench isolation region meet.

4. The method of claim 3, wherein performing the wet etching process substantially removes the byproduct layer.

5. The method of claim 1, comprising:
forming a source/drain region of a transistor in the semiconductor fin after forming the gate spacer layer;
removing the sacrificial gate structure after forming the source/drain region; and
forming a gate metal of the transistor by forming a gate metal in place of the sacrificial gate structure after removing the sacrificial gate structure.

6. The method of claim 5, comprising:
forming, from the semiconductor fin, a plurality of stacked channels of the transistor; and
forming a gate dielectric layer on the channels and on the substrate below the channels, wherein forming the gate metal includes forming the gate metal wrapped around the channels and in contact with the gate dielectric.

7. The method of claim 6, wherein a vertical thickness of the gate metal between the substrate and a bottom channel of the plurality of channels is substantially equal to a vertical thickness of the gate metal between the bottom channel and next highest channel of the plurality of channels.

8. The method of claim 6, wherein the channels each have a same substantially uniform vertical thickness.

9. The method of claim 6, comprising:
forming a dielectric inner spacer vertically between the substrate and bottom channel of the plurality of channels; and
forming the gate dielectric in contact with dielectric the inner spacer and the gate spacer layer, wherein in a lateral plane the gate dielectric layer bends at a junction of the inner spacer and the gate spacer layer, wherein a bend of the gate dielectric layer makes an angle between 150 degrees and 165 degrees at the junction.

10. The method of claim 9, wherein a distance between the gate dielectric layer and the source/drain region at the junction is greater than 5 nm.

11. The method of claim 9, wherein the bend results from a curve in a surface of the inner spacer.

12. The method of claim 6, comprising:
forming a plurality of sacrificial dielectric nanostructures interleaved with the channels;
removing the sacrificial dielectric structures after removing the sacrificial gate structure; and
forming the gate metal in place of the sacrificial dielectric nanostructures.

13. A method, comprising:
forming a semiconductor fin above a substrate of a wafer and extending in a first direction;
forming a sacrificial gate structure overlying the semiconductor fin and extending in a second direction perpendicular to the first direction;
removing a byproduct layer from the sacrificial gate structure by performing a multi-step etching process including a dry etching process followed by a wet etching process;
forming a plurality of channels of a transistor from the semiconductor fin after the multi-step etching process;
forming a plurality of sacrificial dielectric nanostructures between the channels; and
replacing the sacrificial gate structure and the sacrificial dielectric nanostructures with a gate metal of the transistor.

14. The method of claim 13, wherein performing the multi-step etching process includes:
transferring the wafer to a dry etching tool after forming the sacrificial gate structure; and
transferring the wafer to a wet etching tool after transferring the wafer to the dry etching tool.

15. The method of claim 14, comprising performing a plasma etching process on the wafer with the dry etching tool, including:
flowing HF or NH3 as an etch gas; and
flowing a passivation gas including N2, O2, or CO2 with the etch gas.

16. The method of claim 13, wherein forming the plurality of channels includes defining the channels from a stack of semiconductor layers of the semiconductor fin by forming source/drain trenches in the semiconductor fin after performing the multi-step etching process.

17. The method of claim 16, comprising forming source/drain regions of the transistor in the source/drain trenches.

18. A device, comprising:
a substrate;
a transistor including:
a plurality of stacked channels above the substrate;
an inner spacer between a bottom channel of the stacked channels and the substrate;
a gate spacer layer;
a gate dielectric layer in contact with the inner spacer and the gate spacer layer at junction of the gate spacer layer and the inner spacer layer; and
a gate metal wrapped around the channels and in contact with the gate dielectric between the substrate and the bottom channel, wherein the inner spacer layer bends, in a lateral plane, at the junction with an angle between 150 degrees and 180 degrees.

19. The device of claim 18, wherein the channels each have substantially uniform vertical thickness.

20. The device of claim 18, wherein a distance between the gate dielectric layer and the source/drain region at the junction is greater than 5 nm.
